(19) United States
(12) Patent Application Publication
(10) Pub. No.: US 2006/0290405 A1
(43) Pub. Date: Dec. 28, 2006

(54) Level shifter and method thereof

(75) Inventors: Min-Su Kim, Hwaseong-si (KR); Young-Min Shin, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/471,624

(22) Filed: Jun. 21, 2006

(30) Foreign Application Priority Data
Jun. 22, 2005 (KR) 10-2005-0053904

(51) Int. Cl. H03L 5/00

(52) U.S. Cl. 327/333

(57) ABSTRACT

A level shifter and method thereof. The example level shifter may include a level shifting unit generating a plurality of internal voltages, shifting the voltage levels of a plurality of input signals and outputting an output signal based at least in part on the plurality of internal voltages and a mode control unit controlling the voltage levels of the plurality of internal voltages in response to a mode selection signal. The example method may include generating a plurality of internal voltages based on a plurality of input signals, controlling the voltage levels of the plurality of internal voltages based on a mode selection signal and outputting an output signal based at least in part on the plurality of internal voltages.

### PRIORITY STATEMENT

This application claims the benefit of Korean Patent Application No. 10-2005-0053904, filed on Jun. 22, 2005, in the Korean Intellectual Property Office, the disclosure of which is incorporated herein in its entirety by reference.

### BACKGROUND OF THE INVENTION

1. Field of the Invention

Example embodiments of the present invention relate to a level shifter and method thereof, and more particularly, to a level shifter capable of level shifting based at least in part on a mode selection signal and method thereof.

2. Description of the Related Art

A conventional mobile device may be required to maintain a threshold degree of performance for a long period of time using a relatively limited battery. Accordingly, power conservation may be a factor in the design of conventional mobile devices.

In an example conventional power conservation technique, a plurality of circuits included in the mobile device may be divided into a plurality of function blocks based on their functions, and each of the plurality of function blocks may be configured for operation with different voltages. For example, a higher power supply voltage may be applied to function blocks processing data at a higher speed even if more energy is consumed, and a lower power supply voltage may be applied to simple function blocks which do not perform higher-speed processing.

Function blocks using different power supply voltages may output signals at different voltage levels. The signals from the different function blocks may be transferred between function blocks through a level shifter interface to account for the different voltage levels.

FIG. 1 is a block diagram of a conventional mobile system 100. Referring to FIG. 1, the mobile system 100 may include a first function block 110, a first level shifter 120, a second function block 130, a second level shifter 140, a third function block 150 and a third level shifter 160.

The first function block 110 may be operated between a first power supply voltage VDD1 and a ground voltage VSS and may output a first signal S1 based on an input signal IN and the output signal S6 of the third level shifter 160. The first level shifter 120 may be operated between a second power supply voltage VDD2 and the ground voltage VSS and may output a second signal S2 having a voltage level shifted from the voltage level of the first signal S1. The second function block 130 may be operated between the second power supply voltage VDD2 and the ground voltage VSS and may output a third signal S3 based on the second signal S2. The second level shifter 140 may be operated between a third power supply voltage VDD3 and the ground voltage VSS and may output a fourth signal S4 having a voltage level shifted from the voltage level of the third signal S3. The third function block 150 may be operated between the third power supply voltage VDD3 and the ground voltage VSS and may output a fifth signal S5 based on the fourth signal S4. The third level shifter 160 may be operated between the first power supply voltage VDD1 and the ground voltage VSS and may output the sixth signal S6 having a voltage level shifted from the voltage level of the third signal S3.

Referring to FIG. 1, the first, second and third level shifters 120, 140 and 150 arranged between the function blocks 110, 130 and 150 may shift the voltage levels of received signals to voltage levels suitable for being used in function blocks to which the signals may be transmitted.

For example, the first level shifter 120 may shift the voltage level of the received first signal S1 to a voltage level suitable for the second function block 130 to generate the second signal S2 having the shifted voltage level. Because the first level shifter 120 may be operated between the second power supply voltage VDD2 and the ground voltage VSS, the second signal S2 may likewise swing between the second power supply voltage VDD2 and the ground voltage VSS. Thus, the voltage level of the second signal S2 may be suitable for a voltage level of the input signal of the second function block 130 operated between the second power supply voltage VDD2 and the ground voltage VSS. The third level shifter 160 may shift the voltage level of the third signal S3 to a voltage level suitable for the first function block 110 to generate the sixth signal S6 having the shifted voltage level. Because the third level shifter 140 may be operated between the first power supply voltage VDD1 and the ground voltage VSS, the sixth signal S6 may swing between the first power supply voltage VDD1 and the ground voltage VSS. Thus, the first function block 110, which may be operated between the first power supply voltage VDD1 and the ground voltage VSS in response to the sixth signal S6, may function normally.

FIGS. 2 through 4 illustrate conventional level shifters 200, 300 and 400, respectively. A process of generating an output signal Y using two input signals A and NA in each of the conventional level shifters 200, 300 and 400 will be readily understood by one of ordinary skill in the art, and as such has been omitted for the sake of brevity.

If power supplied to function blocks and level shifters is turned off in order to reduce power consumption of a system, output terminals of the function blocks and level shifters to which power is not supplied may transition to a higher impedance state or a meta-stable state, e.g., invalid signals may appear on the respective output terminals.

In the higher impedance state, the voltages of the output terminals (e.g., of the function blocks, the level shifters, etc.) may not be fixed to specific values, but rather may vary randomly. Accordingly, if the system receives the “random” voltage signals output from the output terminals in the higher impedance state and operates in response to the voltage signals, the corresponding function blocks receiving the “random” voltage signals may not operate normally.

In the meta-stable state, signals output from the output terminals (e.g., of the function blocks, the level shifters, etc.) may have voltage levels between a voltage level corresponding to a first logic level (e.g., a higher logic level or “1”) and a voltage level corresponding to a second logic level (e.g., a lower logic level or “0”). If a meta-stable signal is applied to a CMOS inverter, a P-type MOS transistor and an N-type MOS transistor (e.g., which may collectively form the CMOS inverter) may be simultaneously turned on, which may increase a power consumption of the CMOS inverter.

As described above, if a signal is output from a function block, which is not powered and has no fixed voltage level, to a level shifter and the voltage level of the signal is shifted by the level shifter, and the shifted signal is transferred from the level shifter to another function block, the corresponding function block receiving the level shifted signal may not operate normally.

### SUMMARY OF THE INVENTION

An example embodiment of the present invention is directed to a level shifter, including a level shifting unit generating a plurality of internal voltages, shifting the voltage levels of a plurality of input signals and outputting an output signal based at least in part on the plurality of internal voltages and a mode control unit controlling the voltage levels of the plurality of internal voltages in response to a mode selection signal.

Another example embodiment of the present invention is directed to a method of level shifting, including generating a plurality of internal voltages based on a plurality of input signals, controlling the voltage levels of the plurality of internal voltages based on a mode selection signal and outputting an output signal based at least in part on the plurality of internal voltages.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a block diagram of a conventional mobile system.

FIG. 2 illustrates a conventional level shifter.

FIG. 3 illustrates another conventional level shifter.

FIG. 4 illustrates another conventional level shifter.

FIG. 5 is a block diagram of a level shifter having a mode selection function according to an example embodiment of the present invention.

FIG. 6 is a circuit diagram illustrating a level shifter according to another example embodiment of the present invention.

FIG. 7 is a circuit diagram illustrating another level shifter according to another example embodiment of the present invention.

FIG. 8 is a circuit diagram illustrating another level shifter according to another example embodiment of the present invention.

FIG. 9 is a circuit diagram illustrating another level shifter according to another example embodiment of the present invention.

FIG. 10 is a circuit diagram illustrating another level shifter according to another example embodiment of the present invention.

FIG. 11 is a circuit diagram illustrating another level shifter according to another example embodiment of the present invention.

FIG. 12 is a circuit diagram illustrating another level shifter according to another example embodiment of the present invention.

FIG. 13 is a circuit diagram illustrating another level shifter according to another example embodiment of the present invention.

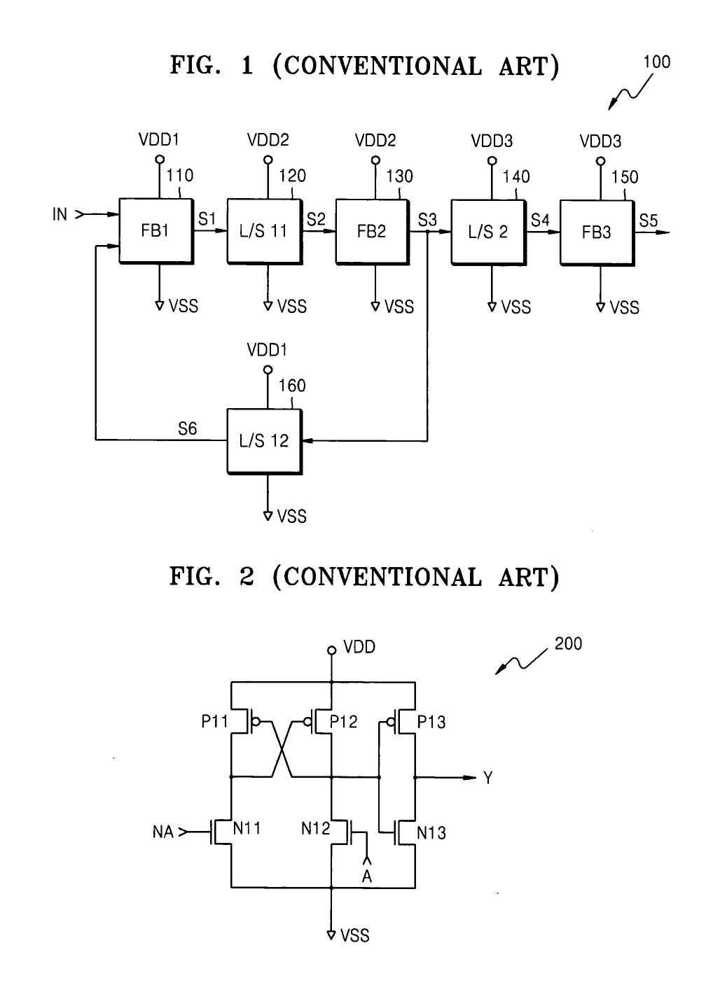

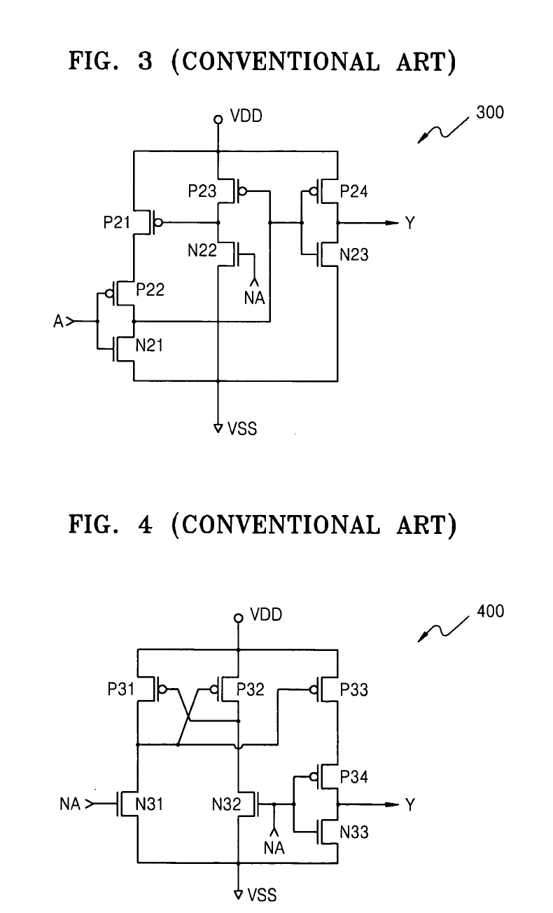

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

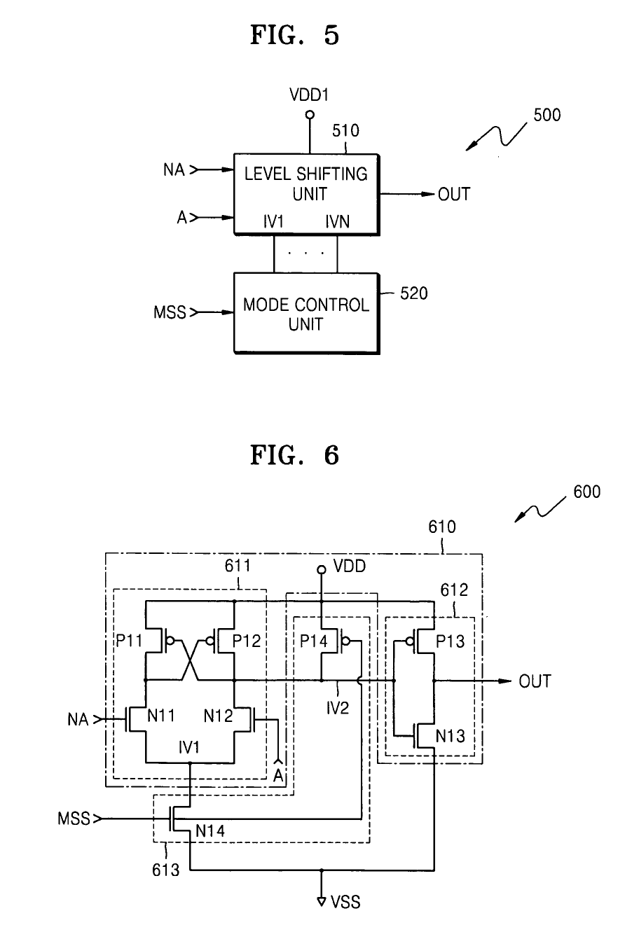

FIG. 5 is a block diagram of a level shifter 500 having a mode selection function according to an example embodiment of the present invention. In the example embodiment of FIG. 5, the level shifter 500 may include a level shifting unit 510 and a mode control unit 520.

In the example embodiment of FIG. 5, the level shifting unit 510 may generate a plurality of internal voltages IV1 through IVN, where N may be a positive integer. The level shifting unit 510 may further shift the voltage levels of input signals NA and A, and may output the shifted input signals through an output terminal OUT. The mode control unit 520 may shift the plurality of internal voltages IV1 through IVN in response to a mode selection signal MSS. The input signals NA and A may be applied to the level shifting unit 510 from a function block (not shown), and the signal OUT output through the output terminal OUT may be applied to one or more other function blocks (not shown). In the example embodiment of FIG. 5, both the output terminal and the output signal may be denoted as OUT.

In an example, referring to FIG. 5, if a function block (not shown) outputting the input signals NA and A to the level shifting unit 510 receives a power supply supplied at a voltage above an operating voltage threshold, the function block may operate in a normal mode. Alternatively, if the power supply supplied to the function block is reduced (e.g., turned off, below the operating voltage threshold, etc.), the function block may operate in a power saving mode referred to as a power down mode.

In the example embodiment of FIG. 5, one of the normal mode and the power down mode may be designated by a voltage level of the mode selection signal MSS. For example, the voltage level of the mode selection signal MSS may be higher in the normal mode than in the power down mode. In an alternative example, the voltage level of the mode selection signal MSS may be lower in the normal mode than in the power down mode.

In the example embodiment of FIG. 5, the level shifter 500 may output signals having voltage levels shifted from the voltage levels of the input signals NA and A through the output terminal OUT based on the plurality of internal voltage IV1 through WN and the input signals NA and A if the mode selection signal MSS designates the normal mode. Alternatively, if the mode selection signal MSS designates the power down mode, the level shifter 500 may output a given DC voltage value through the output terminal OUT in response to the internal voltages IV1 through WN. The given DC voltage value may be based on a voltage value of the mode selection signal MSS. Moreover, it can be that the signal on the output terminal OUT (in power down mode) substantially is not determined according to, e.g., irrespective of, the input signals NA and A.

In the example embodiment of FIG. 5, the output signal OUT may not transition to a higher impedance state or a meta-stable state in either the power down mode or the normal mode. Also, the level shifter 500 may output the signal OUT having the given DC voltage value in the power down mode, and thus a function block (not shown) receiving the output signal OUT may be normally operated.

FIG. 6 is a circuit diagram illustrating a level shifter 600 according to another example embodiment of the present invention. In an example, the circuit diagram of the level shifter 600 of FIG. 6 may be representative of the level shifter 500 of FIG. 5. In the example embodiment of FIG. 6, the level shifter 600 may include a level shifting unit 610 and a mode control unit 613. The level shifting unit 610 may include a level shift stage 611 and an output buffer stage 612.

In the example embodiment of FIG. 6, the level shift stage 611 may generate a second internal voltage IV2 in response to a first input signal NA, a second input signal A and a first internal voltage IV1. The level shift stage 611 may include a first P-type MOS transistor P11, a second P-type MOS transistor P112, a first N-type MOS transistor N11 and a second N-type MOS transistor N12. With regard to the description of the example embodiment of FIG. 6 as herein provided, it may be assumed that the voltage level of the first internal voltage terminal IV1 is the first internal voltage IV1, the voltage level of the second internal voltage terminal IV2 is the second internal voltage IV2, and the output signal OUT is output from the output terminal OUT.

In the example embodiment of FIG. 6, a first terminal of the first P-type MOS transistor P11 may be coupled to a first power supply voltage VDD and a gate of the first P-type MOS transistor P12 may be coupled to the second internal voltage terminal IV2. A first terminal of the second P-type MOS transistor P12 may be coupled to the first power supply voltage VDD, a second terminal of the P-type MOS transistor P12 may be coupled to the second internal voltage terminal IV2, and a gate of the P-type MOS transistor P12 may be coupled to a second terminal of the first P-type MOS transistor P111. A first terminal of the first N-type MOS transistor N11 may be coupled to the second terminal of the first P-type MOS transistor P11, a second terminal of the first N-type MOS transistor N11 may be coupled to the first internal voltage terminal IV1, and a gate of the first N-type MOS transistor N11 may receive the first input signal NA. A first terminal of the second N-type MOS transistor N12 may be coupled to the second internal voltage terminal IV2, a second terminal of the second N-type MOS transistor N12 may be coupled to the first internal voltage terminal IV1, and a gate of the second N-type MOS transistor N12 may receive the second input signal A.

In the example embodiment of FIG. 6, the output buffer stage 612 may include a third P-type MOS transistor P 13 and a third N-type MOS transistor N13. A first terminal of the third P-type MOS transistor P 13 may be coupled to the first power supply voltage VDD, a second terminal of the third P-type MOS transistor P13 may be coupled to the output terminal OUT, and a gate of the third P-type MOS transistor P13 may be coupled to the second internal voltage terminal IV2. A first terminal of the third N-type MOS transistor N13 may be coupled to the output terminal OUT, a second terminal of the third N-type MOS transistor N13 may be coupled to a second power supply voltage VSS, and a gate of the third N-type MOS transistor N13 may be coupled to the second internal voltage terminal IV2.

In the example embodiment of FIG. 6, the mode control unit 613 may include a fourth N-type MOS transistor N14 and a fourth P-type MOS transistor P14. A first terminal of the fourth N-type MOS transistor N14 may be coupled to the first internal voltage terminal IV1, a second terminal of the fourth N-type MOS transistor N14 may be coupled to the second power supply voltage VSS, and a gate of the fourth N-type MOS transistor N14 may receive the mode selection signal MSS. A first terminal of the fourth P-type MOS transistor P14 may be coupled to the first power supply voltage VDD, a second terminal of the fourth P-type MOS transistor P14 may be coupled to the second internal voltage terminal IV2, and a gate of the fourth P-type MOS transistor P14 may receive the mode selection signal MSS.

In the example embodiment of FIG. 6, if the level shifter 600 is operating in the normal mode, the mode selection signal MSS may have a voltage level higher than a first threshold voltage capable of turning on the fourth N-type MOS transistor N14. The fourth P-type MOS transistor P14 may thereby be turned off. The voltage level and phase of the output signal OUT may be determined based on the two input signals NA and A and the first internal voltage IV1.

In the example embodiment of FIG. 6, if the level shifter 600 is operating in the power down mode, the mode selection signal MSS may have a voltage level lower than a second threshold voltage capable of turning on the fourth P-type MOS transistor P 14. The fourth N-type MOS transistor N14 may thereby be turned off. If the fourth P-type MOS transistor P14 is turned on such that the second internal voltage IV2 has a value approximating the first power supply voltage VDD, the voltage level of the output terminal OUT may substantially match the voltage level of the second power supply voltage VSS corresponding to a second logic level (e.g., a lower logic level or logic “0”) irrespective of the two input signals NA and A. Also, the fourth N-type MOS transistor N14 may be turned off such that current may not flow therein. Thus, the level shift stage 611 may consume a reduced amount of power in the power down mode, thereby decreasing power consumption of the level shifter 600 as well as any function blocks relying upon signals output from the level shifter 600.

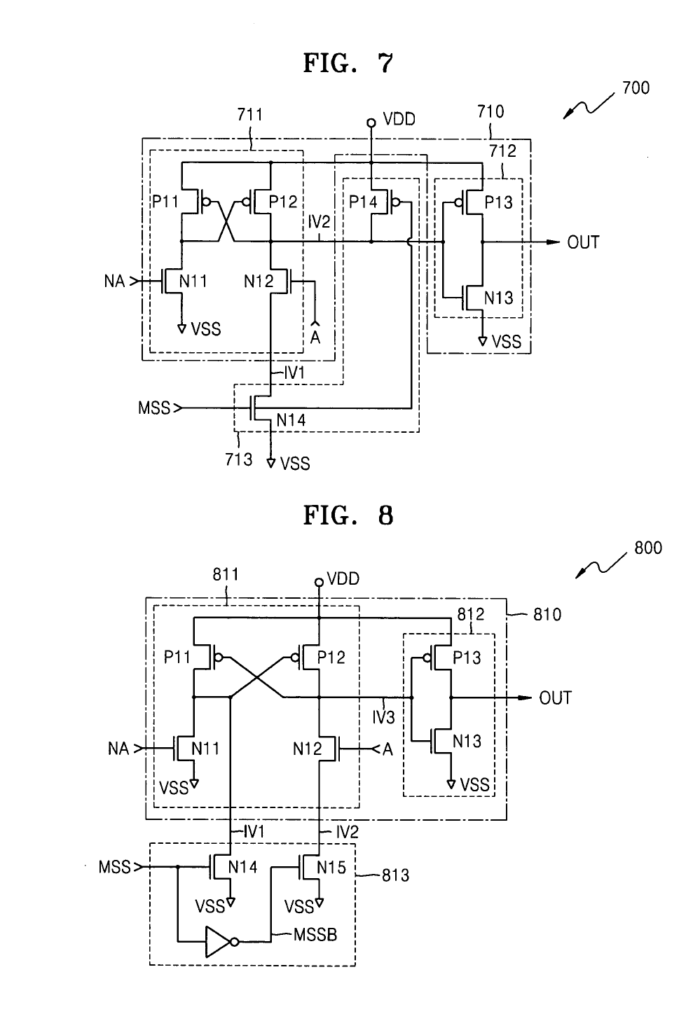

FIG. 7 is a circuit diagram illustrating a level shifter 700 according to another example embodiment of the present invention. In an example, the circuit diagram of the level shifter 700 of FIG. 7 may be representative of the level shifter 500 of FIG. 5, and may be illustrative of an alternative to the level shifter 600 of FIG. 6. In the example embodiment of FIG. 6, the level shifter 700 may include a level shifting unit 710 and a mode control unit 713. The level shifting unit 710 may include a level shift stage 711 and an output buffer stage 712.

In the example embodiment of FIG. 7, the level shift stage 711 may generate a second internal voltage IV2 in response to a first input signal NA, a second input signal A and a first internal voltage IV1. The level shift stage 711 may include a first P-type MOS transistor P11, a second P-type MOS transistor P12, a first N-type MOS transistor N11 and a second N-type MOS transistor N12.

In the example embodiment of FIG. 7, a first terminal of the first P-type MOS transistor P11 may be coupled to a first power supply voltage VDD and a gate of the first P-type MOS transistor P11 may be coupled to the second internal voltage terminal IV2. A first terminal of the second P-type MOS transistor P12 may be coupled to the first power supply voltage VDD, a second terminal of the second P-type MOS transistor P12 may be coupled to the second internal voltage terminal IV2, and a gate of the second P-type MOS transistor P12 may be coupled to a second terminal of the first P-type MOS transistor P11. A first terminal of the first N-type MOS transistor N 1I may be coupled to the second terminal of the first P-type MOS transistor P111, a second terminal of the first N-type MOS transistor N11 may be coupled to a second power supply voltage VSS, and a gate of the first N-type MOS transistor N11 may receive the first input signal NA. A first terminal of the second N-type MOS transistor N12 may be coupled to the second internal voltage terminal IV2, a second terminal of the second N-type MOS transistor N12 may be coupled to the first internal voltage terminal IV1, and a gate of the second N-type MOS transistor N12 may receive the second input signal A.

In the example embodiment of FIG. 7, the output buffer stage 712 and the mode control unit 713 may be identical to the output buffer stage 612 and the mode control unit 613 of FIG. 6, respectively. Accordingly, a description of the output buffer stage 712 and the mode control unit 713 has been omitted for the sake of brevity.

In another example, a difference between the example embodiments of FIGS. 6 and 7 is that the second terminal of the first N-type MOS transistor N11 of the level shifter 700 of FIG. 7 may be directly coupled to the second power supply voltage VSS and the second terminal of the first N-type MOS transistor N 1I of the level shifter 600 of FIG. 6 may be coupled to the first internal voltage terminal IV1. Example operation of the level shifter 700 in both the normal mode and power down mode may be the same as the above-described operation of the level shifter 600, and accordingly a further description of the operation of the level shifter 700 has been omitted for the sake of brevity.

FIG. 8 is a circuit diagram illustrating a level shifter 800 according to another example embodiment of the present invention. In an example, the circuit diagram of the level shifter 800 of FIG. 8 may be representative of the level shifter 500 of FIG. 5, and may be illustrative of an alternative to the level shifter 600 of FIG. 6 and/or the level shifter 700 of FIG. 7. In the example embodiment of FIG. 8, the level shifter 800 may include a level shifting unit 810 and a mode control unit 813. The level shifting unit 810 may include a level shift stage 811 and an output buffer stage 812.

In the example embodiment of FIG. 8, the level shift stage 811 may generate a third internal voltage IV3 in response to a first input signal NA, a second input signal A, a first internal voltage IV1 and a second internal voltage IV2. The level shift stage 811 may include a first P-type MOS transistor P11, a second P-type MOS transistor P12, a first N-type MOS transistor N11 and a second N-type MOS transistor N12.

In the example embodiment of FIG. 8, a first terminal of the first P-type MOS transistor P11 may be coupled to a first power supply voltage VDD, a second terminal of the first P-type MOS transistor P11 may be coupled to the first internal voltage terminal IV1, and a gate of the first P-type MOS transistor P11 may be coupled to the third internal voltage terminal IV3. A first terminal of the second P-type MOS transistor P12 may be coupled to the first power supply voltage VDD, a second terminal of the second P-type MOS transistor P12 may be coupled to the third internal voltage terminal IV3, and a gate of the second P-type MOS transistor P12 may receive the first internal voltage IV1. A first terminal of the first N-type MOS transistor N11 may be coupled to the first internal voltage terminal IV1, a second terminal of the first N-type MOS transistor N11 may be coupled to a second power supply voltage VSS, and a gate of the first N-type MOS transistor N11 may receive the first input signal NA. A first terminal of the second N-type MOS transistor N12 may be coupled to the third internal voltage terminal IV3, a second terminal of the second N-type MOS transistor N12 may be coupled to the second internal voltage terminal IV2, and a gate of the second N-type MOS transistor N12 may receive the second input signal A.

In the example embodiment of FIG. 8, the output buffer stage 812 may include a third P-type MOS transistor P13 and a third N-type MOS transistor N 13. A first terminal of the third P-type MOS transistor P 13 may be coupled to the first power supply voltage VDD, a second terminal of the third P-type MOS transistor P13 may be coupled to the output terminal OUT, and a gate of the third P-type MOS transistor P 13 may be coupled to the third internal voltage terminal IV3. A first terminal of the third N-type MOS transistor N13 may be coupled to the output terminal OUT, a second terminal of the third N-type MOS transistor N13 may be coupled to the second power supply voltage VSS, and a gate of the third N-type MOS transistor N13 may be coupled to the third internal voltage terminal IV3.

In the example embodiment of FIG. 8, the mode control unit 813 may include a fourth N-type MOS transistor N14 and a fifth N-type MOS transistor N15. A first terminal of the fourth N-type MOS transistor N14 may be coupled to the first internal voltage terminal IV1, a second terminal of the fourth N-type MOS transistor N14 may be coupled to the second power supply voltage VSS, and a gate of the fourth N-type MOS transistor N14 may receive the mode selection signal MSS. A first terminal of the fifth N-type MOS transistor N15 may be coupled to the second internal voltage terminal IV2, a second terminal of the fifth N-type MOS transistor N15 may be coupled to the second power supply voltage VSS, and a gate of the fifth N-type MOS transistor N15 may receive a reverse mode selection signal MSSB having a phase opposite to that of the mode selection signal MSS. The mode control unit 813 may further include an inverter INV for generating the reverse mode selection signal MSSB.

In the example embodiment of FIG. 8, one of the fourth and fifth N-type MOS transistors N14 and N15 may be turned off when the other is turned on because the mode selection signal MSS and the reverse mode selection signal MSSB (e.g., with opposite logic levels) may be respectively applied to the gates of the fourth and fifth N-type MOS transistors N14 and M15.

In the example embodiment of FIG. 8, if the level shifter 800 is operating in the normal mode, the fourth N-type MOS transistor N14 may be turned off and the fifth N-type MOS transistor N15 may be turned on. Thus, the level shifter 800 may output an output signal OUT in response to the two input signals NA and A.

In the example embodiment of FIG. 8, if the level shifter 800 is operating in the power down mode, the fourth N-type MOS transistor N14 may be turned on and the fifth N-type MOS transistor N15 may be turned off. Thus, the level shifter 800 may output an output signal OUT having the same voltage value as the second power supply voltage VSS through the output terminal OUT irrespective of the voltage levels of the two input signals NA and A.

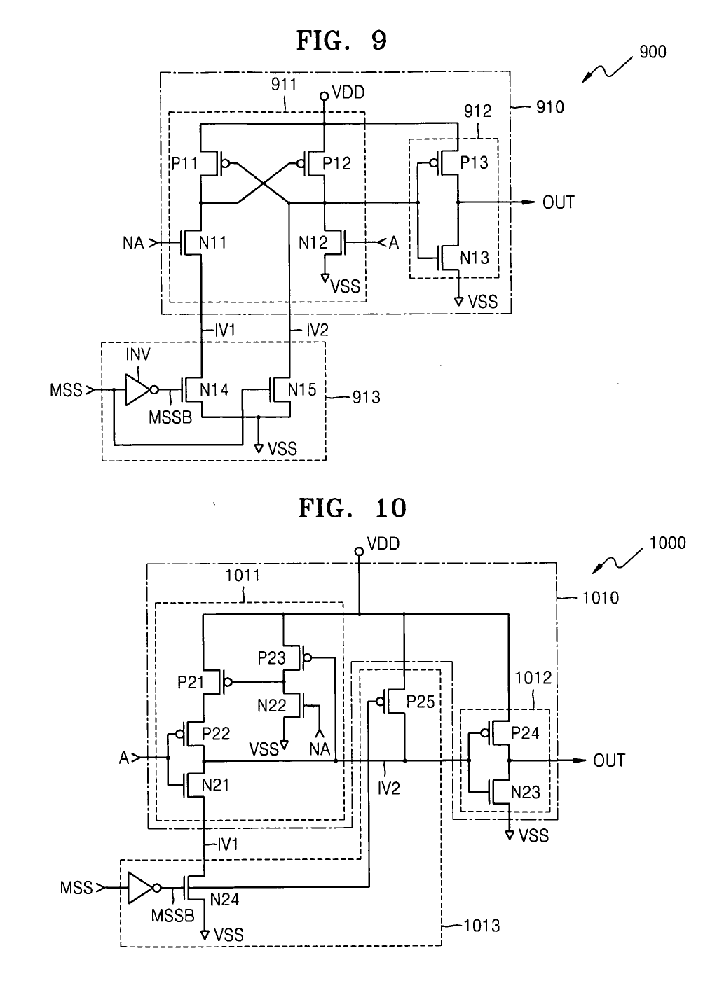

FIG. 9 is a circuit diagram illustrating a level shifter 900 according to another example embodiment of the present invention. In an example, the circuit diagram of the level shifter 900 of FIG. 9 may be representative of the level shifter 500 of FIG. 5, and may be illustrative of an alternative to the level shifters, 600, 700 and 800 of FIGS. 6, 7 and 8, respectively. In the example embodiment of FIG. 9, the level shifter 900 may include a level shifting unit 910 and a mode control unit 913. The level shifting unit 910 may include a level shift stage 911 and an output buffer stage 912.

In the example embodiment of FIG. 9, the level shift stage 911 may generate a second internal voltage IV2 in response to a first input signal NA, a second input signal A and a first internal voltage IV1. The level shift stage 911 may include a first P-type MOS transistor P11, a second P-type MOS transistor P12, a first N-type MOS transistor N11 and a second N-type MOS transistor N12.

In the example embodiment of FIG. 9, a first terminal of the first P-type MOS transistor P11 may be coupled to a first power supply voltage VDD and a gate of the first P-type MOS transistor P11 may be coupled to the second internal voltage terminal IV2. A first terminal of the second P-type MOS transistor P12 may be coupled to the first power supply voltage VDD, a second terminal of the P-type MOS transistor P 12 may be coupled to the second internal voltage terminal IV2, and a gate of the P-type MOS transistor P12 may be coupled to the second terminal of the first P-type MOS transistor P 11. A first terminal of the first N-type MOS transistor N11 may be coupled to the second terminal of the first P-type MOS transistor P111, a second terminal of the first N-type MOS transistor N11 may be coupled to the first internal voltage terminal IV1, and a gate of the first N-type MOS transistor N11 may receive the first input signal NA. A first terminal of the second N-type MOS transistor N12 may be coupled to the second internal voltage terminal IV2, a second terminal of the second N-type MOS transistor N12 may be coupled to a second power supply voltage VSS, and a gate of the second N-type MOS transistor N12 may receive the second input signal A.

In the example embodiment of FIG. 9, the output buffer stage 912 may include a third P-type MOS transistor P13 and a third N-type MOS transistor N13. A first terminal of the third P-type MOS transistor P 13 may be coupled to the first power supply voltage VDD, a second terminal of the third P-type MOS transistor P13 may be coupled to the output terminal OUT, and a gate of the third P-type MOS transistor P13 may be coupled to the second internal voltage terminal IV2. A first terminal of the third N-type MOS transistor N13 may be coupled to the output terminal OUT, a second terminal of the third N-type MOS transistor N13 may be coupled to the second power supply voltage VSS, and a gate of the third N-type MOS transistor N13 may be coupled to the second internal voltage terminal IV2.

In the example embodiment of FIG. 9, the mode control unit 913 may include a fourth N-type MOS transistor N14 and a fifth N-type MOS transistor N15. A first terminal of the fourth N-type MOS transistor N14 may be coupled to the first internal voltage terminal IV1, a second terminal of the fourth N-type MOS transistor N14 may be coupled to the second power supply voltage VSS, and a gate of the fourth N-type MOS transistor N14 may receive a reverse mode selection signal MSSB having a phase opposite to that of the mode selection signal MSS. A first terminal of the fifth N-type MOS transistor N15 may be coupled to the second internal voltage terminal IV2, a second terminal of the fifth N-type MOS transistor N15 may be coupled to the second power supply voltage VSS, and a gate of the fifth N-type MOS transistor N15 may receive the mode selection signal MSS. The mode control unit 913 may further include an inverter NV for generating the reverse mode selection signal MSSB.

In the example embodiment of FIG. 9, one of the fourth and fifth N-type MOS transistors N14 and N15 may be turned off when the other one is turned on because the mode selection signal MSS and the reverse mode selection signal MSSB (e.g., having opposite logic levels) may be respectively applied to the gate of the fifth N-type MOS transistors M15 and the gate of the fourth N-type MOS transistor N14.

In the example embodiment of FIG. 9, if the level shifter 900 is operating in the normal mode, the fourth N-type MOS transistor N14 may be turned on and the fifth N-type MOS transistor N15 may be turned off. Thus, the level shifter 900 may output an output signal OUT in response to the two input signals NA and A and the first internal voltage IV1.

In the example embodiment of FIG. 9, if the level shifter 900 is operating in the power down mode, the fourth N-type MOS transistor N14 may be turned off and the fifth N-type MOS transistor N15 may be turned on. Thus, the level shifter 900 may output an output signal OUT having the same voltage value as the first power supply voltage VDD irrespective of the voltage levels of the two input signals NA and A and the first internal voltage IV1.

FIG. 10 is a circuit diagram illustrating a level shifter 1000 according to another example embodiment of the present invention. In an example, the circuit diagram of the level shifter 1000 of FIG. 10 may be representative of the level shifter 500 of FIG. 5, and may be illustrative of an alternative to the level shifters, 600, 700, 800 and 900 of FIGS. 6, 7, 8 and 9, respectively. In the example embodiment of FIG. 10, the level shifter 1000 may include a level shifting unit 1010 and a mode control unit 1013. The level shifting unit 1010 may include a level shift stage 1011 and an output buffer stage 1012.

In the example embodiment of FIG. 10, the level shift stage 1011 may generate a second internal voltage IV2 in response to a first input signal NA, a second input signal A and a first internal voltage IV1. The level shift stage 1011 may include a first P-type MOS transistor P21, a second P-type MOS transistor P22, a third P-type MOS transistor P23, a first N-type MOS transistor N21 and a second N-type MOS transistor N22.

In the example embodiment of FIG. 10, a first terminal of the first P-type MOS transistor P21 may be coupled to a first power supply voltage VDD. A first terminal of the second P-type MOS transistor P22 may be coupled to a second terminal of the first P-type MOS transistor P21, a second terminal of the second P-type MOS transistor P22 may be coupled to the second internal voltage terminal IV2, and a gate of the second P-type MOS transistor P22 may receive the second input signal A. A first terminal of the third P-type MOS transistor P23 may be coupled to the first power supply voltage VDD, a second terminal of the third P-type MOS transistor P23 may be coupled to the gate of the first P-type MOS transistor P21, and a gate of the third P-type MOS transistor P23 may be coupled to the second internal voltage terminal IV2. A first terminal of the first N-type MOS transistor N21 may be coupled to the second internal voltage terminal IV2, a second terminal of the first N-type MOS transistor N21 may be coupled to the first internal voltage terminal IV1, and a gate of the first N-type MOS transistor N21 may receive the second input signal A. A first terminal of the second N-type MOS transistor N22 may be coupled to the second terminal of the third P-type MOS transistor P23, a second terminal of the second N-type MOS transistor N22 may be coupled to a second power supply voltage VSS, and a gate of the second N-type MOS transistor N22 may receive the first input signal NA.

In the example embodiment of FIG. 10, the output buffer stage 1012 may include a fourth P-type MOS transistor P24 and a third N-type MOS transistor N23. A first terminal of the fourth P-type MOS transistor P24 may be coupled to the first power supply voltage VDD, a second terminal of the fourth P-type MOS transistor P24 may be coupled to the output terminal OUT, and a gate of the fourth P-type MOS transistor P24 may be coupled to the second internal voltage terminal IV2. A first terminal of the third N-type MOS transistor N23 may be coupled to the output terminal OUT, a second terminal of the third N-type MOS transistor N23 may be coupled to the second power supply voltage VSS, and a gate of the third N-type MOS transistor N23 may be coupled to the second internal voltage terminal IV2.

In the example embodiment of FIG. 10, the mode control unit 1013 may include a fourth N-type MOS transistor N24 and a fifth P-type MOS transistor P25. A first terminal of the fourth N-type MOS transistor N24 may be coupled to the first internal voltage terminal IV1, a second terminal of the fourth N-type MOS transistor N24 may be coupled to the second power supply voltage VSS, and a gate of the fourth N-type MOS transistor N24 may receive a reverse mode selection signal MSSB having a phase opposite to that of the mode selection signal MSS. A first terminal of the fifth P-type MOS transistor P25 may be coupled to the first power supply voltage VDD, a second terminal of the fifth P-type MOS transistor P25 may be coupled to the second internal voltage terminal IV2, and a gate of the fifth P-type MOS transistor P25 may receive the reverse mode selection signal MSSB.

In the example embodiment of FIG. 10, one of the fourth N-type MOS transistor N24 and the fifth p-type MOS transistor P25 may be turned off when the other one is turned on because the mode selection signal MSS may be concurrently applied to the gates of the fourth N-type MOS transistor N24 and the fifth P-type MOS transistor P25.

In the example embodiment of FIG. 10, if the level shifter 1000 is operating in the normal mode, the fourth N-type MOS transistor N24 may be turned on and the fifth P-type MOS transistor P25 may be turned off. Thus, the level shifter 1000 may output an output signal OUT in response to the two input signals NA and A and the first internal voltage IV1.

In the example embodiment of FIG. 10, if the level shifter 1000 is operating in the power down mode, the fourth N-type MOS transistor N24 may be turned off and the fifth P-type MOS transistor P25 may be turned on. Thus, the level shifter 1000 may output an output signal OUT having the same voltage level as the second power supply voltage VSS irrespective of the voltage levels of the two input signals NA and A and the first internal voltage IV1.

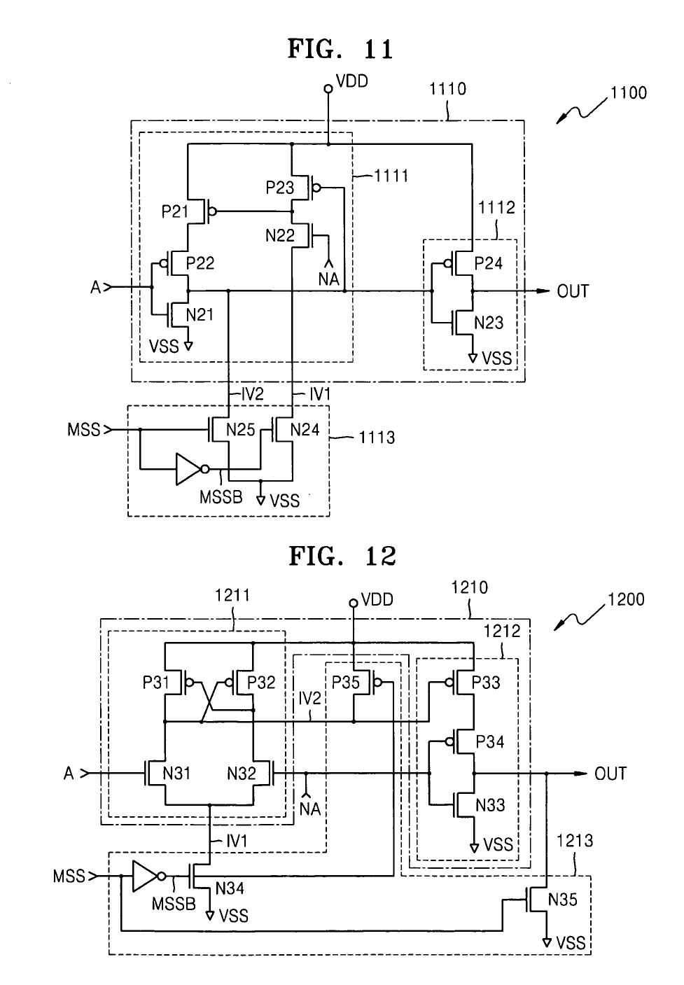

FIG. 11 is a circuit diagram illustrating a level shifter 1100 according to another example embodiment of the present invention. In an example, the circuit diagram of the level shifter 1100 of FIG. 11 may be representative of the level shifter 500 of FIG. 5, and may be illustrative of an alternative to the level shifters, 600, 700, 800, 900 and 1000 of FIGS. 6, 7, 8, 9 and 10, respectively. In the example embodiment of FIG. 11, the level shifter 1100 may include a level shifting unit 1110 and a mode control unit 1113. The level shifting unit 1110 may include a level shift stage 1111 and an output buffer stage 1112.

In the example embodiment of FIG. 11, the level shift stage 1111 may generate a second internal voltage IV2 in response to a first input signal NA, a second input signal A and a first internal voltage IV1. The level shift stage 1111 may include a first P-type MOS transistor P21, a second P-type MOS transistor P22, a third P-type MOS transistor P23, a first N-type MOS transistor N21 and a second N-type MOS transistor N22.

In the example embodiment of FIG. 11, a first terminal of the first P-type MOS transistor P21 may be coupled to a first power supply voltage VDD. A first terminal of the second P-type MOS transistor P22 may be coupled to a second terminal of the first P-type MOS transistor P21, a second terminal of the second P-type MOS transistor P22 may be coupled to the second internal voltage terminal IV2, and a gate of the second P-type MOS transistor P22 may receive the second input signal A. A first terminal of the third P-type MOS transistor P23 may be coupled to the first power supply voltage VDD, a second terminal of the third P-type MOS transistor P23 may be coupled to the gate of the first P-type MOS transistor P21, and a gate of the third P-type MOS transistor P23 may be coupled to the second internal voltage terminal IV2. A first terminal of the first N-type MOS transistor N21 may be coupled to the second internal voltage terminal IV2, a second terminal of the first N-type MOS transistor N21 may be coupled to a second power supply voltage VSS, and a gate of the first N-type MOS transistor N21 may receive the second input signal A. A first terminal of the second N-type MOS transistor N22 may be coupled to the second terminal of the third P-type MOS transistor P23, a second terminal of the second N-type MOS transistor N22 may be coupled to the first internal voltage terminal IV1, and a gate of the second N-type MOS transistor N22 may receive the first input signal NA.

In the example embodiment of FIG. 11, the output buffer stage 1112 may include a fourth P-type MOS transistor P24 and a third N-type MOS transistor N23. A first terminal of the fourth P-type MOS transistor P24 may be coupled to the first power supply voltage VDD, a second terminal of the fourth P-type MOS transistor P24 may be coupled to the output terminal OUT, and a gate of the fourth P-type MOS transistor P24 may be coupled to the second internal voltage terminal IV2. A first terminal of the third N-type MOS transistor N23 may be coupled to the output terminal OUT, a second terminal of the third N-type MOS transistor N23 may be coupled to the second power supply voltage VSS, and a gate of the third N-type MOS transistor N23 may be coupled to the second internal voltage terminal IV2.

In the example embodiment of FIG. 11, the mode control unit 1113 may include a fourth N-type MOS transistor N24 and a fifth N-type MOS transistor N25. A first terminal of the fourth N-type MOS transistor N24 may be coupled to the first internal voltage terminal IV1, a second terminal of the fourth N-type MOS transistor N24 may be coupled to the second power supply voltage VSS, and a gate of the fourth N-type MOS transistor N24 may receive a reverse mode selection signal MSSB having a phase opposite to that of the mode selection signal MSS. A first terminal of the fifth N-type MOS transistor N25 may be coupled to the second internal voltage terminal IV2, a second terminal of the fifth N-type MOS transistor N25 may be coupled to the second power supply voltage VSS, and a gate of the fifth N-type MOS transistor N25 may receive the mode selection signal MSS.

In the example embodiment of FIG. 11, one of the fourth and fifth N-type MOS transistors N24 and N25 may be turned off when the other is turned on because the mode selection signal MSS and the reverse mode selection signal MSSB may be respectively applied to the gate of the fifth N-type MOS transistor N25 and the gate of the fourth N-type MOS transistor N24.

In the example embodiment of FIG. 11, if the level shifter 1100 is operating in the normal mode, the fourth N-type MOS transistor N24 may be turned on and the fifth N-type MOS transistor N25 may be turned off. Thus, the level shifter 1100 may output an output signal OUT in response to the two input signals NA and A and the first internal voltage IV1.

In the example embodiment of FIG. 11, if the level shifter 1100 is operating in the power down mode, the fourth N-type MOS transistor N24 may be turned off and the fifth N-type MOS transistor N25 may be turned on. Thus, the level shifter 1100 may output an output signal OUT having the same voltage level as the first power supply voltage VDD irrespective of the voltage levels of the two input signals NA and A and the first internal voltage IV1.

FIG. 12 is a circuit diagram illustrating a level shifter 1200 according to another example embodiment of the present invention. In an example, the circuit diagram of the level shifter 1200 of FIG. 12 may be representative of the level shifter 500 of FIG. 5, and may be illustrative of an alternative to the level shifters, 600, 700, 800, 900, 1000 and 1100 of FIGS. 6, 7, 8, 9, 10 and 11, respectively. In the example embodiment of FIG. 12, the level shifter 1200 may include a level shifting unit 1210 and a mode control unit 1213. The level shifting unit 1210 may include a level shift stage 1211 and an output buffer stage 1212.

In the example embodiment of FIG. 12, the level shift stage 1211 may generate a second internal voltage IV2 in response to a first input signal NA, a second input signal A and a first internal voltage IV1. The level shift stage 1211 may include a first P-type MOS transistor P31, a second P-type MOS transistor P32, a first N-type MOS transistor N31 and a second N-type MOS transistor N32.

In the example embodiment of FIG. 12, a first terminal of the first P-type MOS transistor P31 may be coupled to a first power supply voltage VDD and a second terminal of the first P-type MOS transistor P31 may be coupled to the second internal voltage terminal IV2. A first terminal of the second P-type MOS transistor P32 may be coupled to the first power supply voltage VDD, a second terminal of the second P-type MOS transistor P32 may be coupled to the gate of the first P-type MOS transistor P31, and a gate of the second P-type MOS transistor P32 may be coupled to the second internal voltage terminal IV2. A first terminal of the first N-type MOS transistor N31 may be coupled to the second internal voltage terminal IV2, a second terminal of the first N-type MOS transistor N31 may be coupled to the first internal voltage terminal IV1, and a gate of the first N-type MOS transistor N31 may receive the second input signal A. A first terminal of the second N-type MOS transistor N32 may be coupled to the second terminal of the second P-type MOS transistor P32, a second terminal of the second N-type MOS transistor N32 may be coupled to the first internal voltage terminal IV1, and a gate of the second N-type MOS transistor N32 may receive the first input signal NA.

In the example embodiment of FIG. 12, the output buffer stage 1212 may include a third P-type MOS transistor P33, a fourth P-type MOS transistor P34 and a third N-type MOS transistor N33. A first terminal of the third P-type MOS transistor P33 may be coupled to the first power supply voltage VDD and a gate of the third P-type MOS transistor P33 may be coupled to the second internal voltage terminal IV2. A first terminal of the fourth P-type MOS transistor P34 may be coupled to the second terminal of the third P-type MOS transistor P33, a second terminal of the fourth P-type MOS transistor P34 may be coupled to the output terminal OUT, and a gate of the fourth P-type MOS transistor P34 may receive the first input signal NA. A first terminal of the third N-type MOS transistor N33 may be coupled to the output terminal OUT, a second terminal of the third N-type MOS transistor N33 may be coupled to a second power supply voltage VSS, and a gate of the third N-type MOS transistor N33 may receive the first input signal NA.

In the example embodiment of FIG. 12, the mode control unit 1213 may include a fourth N-type MOS transistor N34, a fifth N-type MOS transistor N35, and a fifth P-type MOS transistor P35. A first terminal of the fourth N-type MOS transistor N34 may be coupled to the first internal voltage terminal IV1, a second terminal of the fourth N-type MOS transistor N34 may be coupled to the second power supply voltage VSS, and a gate of the fourth N-type MOS transistor N34 may receive a reverse mode selection signal MSSB having a phase opposite to that of the mode selection signal MSS. A first terminal of the fifth N-type MOS transistor N35 may be coupled to the output terminal OUT, a second terminal of the fifth N-type MOS transistor N35 may be coupled to the second power supply voltage VSS, and a gate of the fifth N-type MOS transistor N35 may receive the mode selection signal MSS. A first terminal of the fifth P-type MOS transistor P35 may be coupled to the first power supply voltage VDD, a second terminal of the fifth P-type MOS transistor P35 may be coupled to the second internal voltage terminal IV2, and a gate of the fifth P-type MOS transistor P35 may receive the reverse mode selection signal MSSB.

In the example embodiment of FIG. 12, the reverse mode selection signal MSSB may be applied to the gates of the fourth N-type MOS transistor N34 and the fifth P-type MOS transistor P35 and the mode selection signal MSS may be applied to the gate of the fifth N-type MOS transistor N35. Accordingly, the fourth N-type MOS transistor N34 may be turned off when the fifth N-type MOS transistor N35 and the fifth P-type MOS transistor P35 are turned on. Further, the fourth N-type MOS transistor N34 may be turned on when the fifth N-type MOS transistor N35 and the fifth P-type MOS transistor P35 are turned off.

In the example embodiment of FIG. 12, if the level shifter 1200 is operating in the normal mode, the fourth N-type MOS transistor N34 may be turned on and the fifth N-type MOS transistor N35 and the fifth P-type MOS transistor P35 may be turned off. Thus, the level shifter 1200 may output an output signal OUT in response to the two input signals NA and A and the first internal voltage IV1.

In the example embodiment of FIG. 12, if the level shifter 1200 is operating in the power down mode, the fourth N-type MOS transistor N34 may be turned off and the fifth N-type MOS transistor N35 and the fifth P-type MOS transistor P35 may be turned on. Thus, the level shifter 1200 may output an output signal OUT having the same voltage level as the second power supply voltage VSS irrespective of the voltage levels of the two input signals NA and A and the first internal voltage IV1.

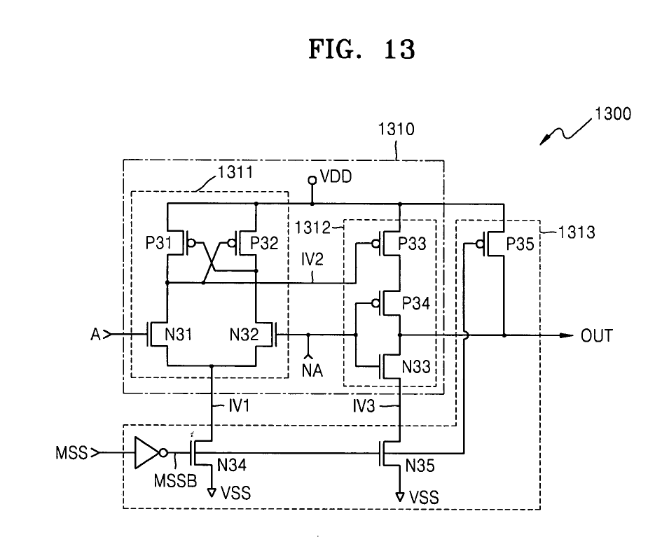

FIG. 13 is a circuit diagram illustrating a level shifter 1300 according to another example embodiment of the present invention. In an example, the circuit diagram of the level shifter 1300 of FIG. 13 may be representative of the level shifter 500 of FIG. 5, and may be illustrative of an alternative to the level shifters, 600, 700, 800, 900, 1000, 1100 and 1200 of FIGS. 6, 7, 8, 9, 10, 11 and 12, respectively. In the example embodiment of FIG. 13, the level shifter 1300 may include a level shifting unit 1310 and a mode control unit 1313. The level shifting unit 1310 may include a level shift stage 1311 and an output buffer stage 1312.

In the example embodiment of FIG. 13, the level shift stage 1311 may generate a second internal voltage IV2 in response to a first input signal NA, a second input signal A and a first internal voltage IV1. The level shift stage 1311 may include a first P-type MOS transistor P31, a second P-type MOS transistor P32, a first N-type MOS transistor N31 and a second N-type MOS transistor N32.

In the example embodiment of FIG. 13, a first terminal of the first P-type MOS transistor P31 may be coupled to a first power supply voltage VDD and a second terminal of the first P-type MOS transistor P31 may be coupled to the second internal voltage terminal IV2. A first terminal of the second P-type MOS transistor P32 may be coupled to the first power supply voltage VDD, a second terminal of the second P-type MOS transistor P32 may be coupled to the gate of the first P-type MOS transistor P31, and a gate of the second P-type MOS transistor P32 may be coupled to the second internal voltage terminal IV2. A first terminal of the first N-type MOS transistor N31 may be coupled to the second internal voltage terminal IV2, a second terminal of the first N-type MOS transistor N31 may be coupled to the first internal voltage terminal IV1, and a gate of the first N-type MOS transistor N31 may receive the second input signal A. A first terminal of the second N-type MOS transistor N32 may be coupled to the second terminal of the second P-type MOS transistor P32, a second terminal of the N-type MOS transistor N32 may be coupled to the first internal voltage terminal IV1, and a gate of the N-type MOS transistor N32 may receive the first input signal NA.

In the example embodiment of FIG. 13, the output buffer stage 1312 may include a third P-type MOS transistor P33, a fourth P-type MOS transistor P34 and a third N-type MOS transistor N33. A first terminal of the third P-type MOS transistor P33 may be coupled to the first power supply voltage VDD and a gate of the third P-type MOS transistor P33 may be coupled to the second internal voltage terminal IV2. A first terminal of the fourth P-type MOS transistor P34 may be coupled to the second terminal of the third P-type MOS transistor P33, a second terminal of the fourth P-type MOS transistor P34 may be coupled to the output terminal OUT, and a gate of the fourth P-type MOS transistor P34 may receive the first input signal NA. A first terminal of the third N-type MOS transistor N33 may be coupled to the output terminal OUT, a second terminal of the third N-type MOS transistor N33 may be coupled to a third internal voltage terminal IV3, and a gate of the third N-type MOS transistor N33 may receive the first input signal NA.

In the example embodiment of FIG. 13, the mode control unit 1313 may include a fourth N-type MOS transistor N34, a fifth N-type MOS transistor N35, and a fifth P-type MOS transistor P35. A first terminal of the fourth N-type MOS transistor N34 may be coupled to the first internal voltage terminal IV1, a second terminal of the fourth N-type MOS transistor N34 may be coupled to the second power supply voltage VSS, and a gate of the fourth N-type MOS transistor N34 may receive a reverse mode selection signal MSSB having a phase opposite to that of the mode selection signal MSS. A first terminal of the fifth N-type MOS transistor N35 may be coupled to the third internal voltage terminal IV3, a second terminal of the fifth N-type MOS transistor N35 may be coupled to the second power supply voltage VSS, and a gate of the fifth N-type MOS transistor N35 may receive the reverse mode selection signal MSSB. A first terminal of the fifth P-type MOS transistor P35 may be coupled to the first power supply voltage VDD, a second terminal of the fifth P-type MOS transistor P35 may be coupled to the output terminal OUT, and a gate of the fifth P-type MOS transistor P35 may receive the reverse mode selection signal MSSB.

In the example embodiment of FIG. 13, the reverse mode selection signal MSSB may be concurrently applied to the gates of the fourth N-type MOS transistor N34, the fifth N-type MOS transistor N35 and the fifth P-type MOS transistor P35. Accordingly, the fifth P-type MOS transistor P35 may be turned off when the fourth and fifth N-type MOS transistors N34 and N35 are turned on. Further, the fifth P-type MOS transistor P35 may be turned on when the fourth and fifth N-type MOS transistors N34 and N35 are turned off.

In the example embodiment of FIG. 13, if the level shifter 1300 is operating in the normal mode, the fourth and fifth N-type MOS transistors N34 and N35 may be turned on and the fifth P-type MOS transistor P35 may be turned off. Thus, the level shifter 1300 may output an output signal OUT in response to the two input signals NA and A and the first internal voltage IV1.

In the example embodiment of FIG. 13, if the level shifter 1300 is operating in the power down mode, the fifth P-type MOS transistor P35 may be turned on and the fourth and fifth MOS transistors N34 and N35 may be turned off. Thus, the level shifter 1300 may output an output signal OUT having the same voltage level as the first power supply voltage VDD irrespective of the voltage levels of the two input signals NA and A and the first internal voltage IV1.

In each of the above-described example level shifters 600 through 1300, a given voltage level may be output irrespective of whether input signals received from a function block are operating in accordance with a power down mode. Accordingly, function blocks operated which receive signals output by the level shifter as inputs may operate normally even of one or more other function blocks may operate in the power down mode.

Example embodiments of the present invention being thus described, it will be obvious that the same may be varied in many ways. For example, it is understood that the above-described first and second logic levels may correspond to a higher level and a lower logic level, respectively, in an example embodiment of the present invention. Alternatively, the first and second logic levels/states may correspond to the lower logic level and the higher logic level, respectively, in other example embodiments of the present invention.

Such variations are not to be regarded as a departure from the spirit and scope of example embodiments of the present invention, and all such modifications as would be obvious to one skilled in the art are intended to be included within the scope of the following claims.

What is claimed is:

1. A level shifter, comprising:
a level shifting unit generating a plurality of internal voltages, shifting the voltage levels of a plurality of input signals and outputting an output signal based at least in part on the plurality of internal voltages; and
a mode control unit controlling the voltage levels of the plurality of internal voltages in response to a mode selection signal.

2. The level shifter of claim 1, wherein the plurality of input signals include a first signal with a first phase and a second signal with a second phase, the first and second phases not being the same.

3. The level shifter of claim 1, wherein the plurality of input signals include a first signal with a first phase and a second signal with a second phase, the first and second phases opposite to each other.

4. The level shifter of claim 1, wherein the mode selection signal indicates either that a given function block outputting the plurality of input signals is operating in a normal mode or that the given function block is operating in a power down mode.

5. The level shifter of claim 3, wherein the output signal of the level shifting unit is based on the plurality of input signals if the mode selection signal indicates the normal mode and is set to a given voltage level if the mode selection signal indicates the power down mode.

6. The level shifter of claim 1, wherein the level shifting unit includes a level shift stage generating the plurality of internal voltages based on the plurality of input signals and an output buffer stage inverting at least part of the plurality of internal voltages and outputting the inverted internal voltage.

7. The level shifter of claim 6, wherein the level shift stage includes:
a first P-type MOS transistor having a first terminal coupled to a first power supply voltage and a gate coupled to a second internal voltage terminal;
a second P-type MOS transistor having a first terminal coupled to the first power supply voltage, a second terminal coupled to the second internal voltage terminal, and a gate coupled to a second terminal of the first P-type MOS transistor;
a first N-type MOS transistor having a first terminal coupled to the second terminal of the first P-type MOS transistor, a second terminal coupled to a first internal voltage terminal, and a gate receiving a first input signal; and
a second N-type MOS transistor having a first terminal coupled to the second internal voltage terminal, a second terminal coupled to the first internal voltage terminal, and a gate receiving a second input signal,
wherein the output buffer stage includes:
a third P-type MOS transistor having a first terminal coupled to the first power supply voltage, a second terminal coupled to an output terminal, and a gate coupled to the second internal voltage terminal; and
a third N-type MOS transistor having a first terminal coupled to the output terminal, a second terminal coupled to a second power supply voltage, and a gate coupled to the second internal voltage terminal,
and wherein the mode control unit includes:
a fourth N-type MOS transistor having a first terminal coupled to the first internal voltage terminal, a second terminal coupled to the second power supply voltage, and a gate receiving the mode selection signal; and
a fourth P-type MOS transistor having a first terminal coupled to the first power supply voltage, a second terminal coupled to the second internal voltage terminal, and a gate receiving the mode selection signal.

8. The level shifter of claim 6, wherein the level shift stage includes:
a first P-type MOS transistor having a first terminal coupled to the first power supply voltage and a gate coupled to the second internal voltage terminal;
a second P-type MOS transistor having a first terminal coupled to the first power supply voltage, a second terminal coupled to the second internal voltage terminal, and a gate coupled to a second terminal of the first P-type MOS transistor;
a first N-type MOS transistor having a first terminal coupled to the second terminal of the first P-type MOS transistor, a second terminal coupled to the second internal voltage terminal, and a gate receiving the first input signal; and
a second N-type MOS transistor having a first terminal coupled to the second internal voltage terminal, a second terminal coupled to the first internal voltage terminal, and a gate receiving the second input signal.

9. The level shifter of claim 6, wherein the level shift stage includes:
a first P-type MOS transistor having a first terminal coupled to the first power supply voltage, a second terminal coupled to the first internal voltage terminal, and a gate coupled to a third internal voltage terminal;
a second P-type MOS transistor having a first terminal coupled to the first power supply voltage, a second terminal coupled to the third internal voltage terminal, and a gate receiving the first internal voltage;
a first N-type MOS transistor having a first terminal coupled to the first internal voltage terminal, a second terminal coupled to the second power supply voltage, and a gate receiving the first input signal; and
a second N-type MOS transistor having a first terminal coupled to the third internal voltage terminal, a second terminal coupled to the second internal voltage terminal, and a gate receiving the second input signal,
wherein the output buffer stage includes:
a third P-type MOS transistor having a first terminal coupled to the first power supply voltage, a second terminal coupled to the output terminal, and a gate coupled to the third internal voltage terminal; and
a third N-type MOS transistor having a first terminal coupled to the output terminal, a second terminal coupled to the second power supply voltage, and a gate coupled to the third internal voltage terminal,
and wherein the mode control unit includes:
a fourth N-type MOS transistor having a first terminal coupled to the first internal voltage terminal, a second terminal coupled to the second power supply voltage, and a gate receiving the mode selection signal; and
a fifth N-type MOS transistor having a first terminal coupled to the second internal voltage terminal, a second terminal coupled to the second power supply voltage, and a gate receiving a reverse mode selection signal having a phase opposite to that of the mode selection signal.

10. The level shifter of claim 6, wherein the level shift stage includes:
a first P-type MOS transistor having a first terminal coupled to the first power supply voltage and a gate coupled to the second internal voltage terminal;
a second P-type MOS transistor having a first terminal coupled to the first power supply voltage, a second terminal coupled to the second internal voltage terminal, and a gate coupled to a second terminal of the first P-type MOS transistor;
a first N-type MOS transistor having a first terminal coupled to the second terminal of the first P-type MOS transistor, a second terminal coupled to the first internal voltage terminal, and a gate receiving the first input signal; and
a second N-type MOS transistor having a first terminal coupled to the second internal voltage terminal, a second terminal coupled to the second power supply voltage, and a gate receiving the second input signal,
wherein the output buffer stage includes:
a third P-type MOS transistor having a first terminal coupled to the first power supply voltage, a second terminal coupled to the output terminal, and a gate coupled to the second internal voltage terminal; and
a third N-type MOS transistor having a first terminal coupled to the output terminal, a second terminal coupled to the second power supply voltage, and a gate coupled to the second internal voltage terminal, and
wherein the mode control unit includes:
a fourth N-type MOS transistor having a first terminal coupled to the first internal voltage terminal, a second terminal coupled to the second power supply voltage, and a gate receiving the reverse mode selection signal; and
a fifth N-type MOS transistor having a first terminal coupled to the second internal voltage terminal, a second terminal coupled to the second power supply voltage, and a gate receiving the mode selection signal.

11. The level shifter of claim 6, wherein the level shift stage includes:
a first P-type MOS transistor having a first terminal coupled to the first power supply voltage;
a second P-type MOS transistor having a first terminal coupled to a second terminal of the first P-type MOS transistor, a second terminal coupled to the second internal voltage terminal, and a gate receiving the second input signal;
a third P-type MOS transistor having a first terminal coupled to the first power supply voltage, a second terminal coupled to the gate of the first P-type MOS transistor, and a gate coupled to the second internal voltage terminal;
a first N-type MOS transistor having a first terminal coupled to the second internal voltage terminal, a second terminal coupled to the first internal voltage terminal, and a gate receiving the second input signal; and
a second N-type MOS transistor having a first terminal coupled to the second terminal of the third P-type MOS transistor, a second terminal coupled to the second power supply voltage, and a gate receiving the first input signal,
wherein the output buffer stage includes:
a fourth P-type MOS transistor having a first terminal coupled to the first power supply voltage, a second terminal coupled to the output terminal, and a gate coupled to the second internal voltage terminal; and
a third N-type MOS transistor having a first terminal coupled to the output terminal, a second terminal coupled to the second power supply voltage, and a gate coupled to the second internal voltage terminal, and
wherein the mode control unit includes:
a fourth N-type MOS transistor having a first terminal coupled to the first internal voltage terminal, a second terminal coupled to the second power supply voltage, and a gate receiving the reverse mode selection signal; and
a fifth P-type MOS transistor having a first terminal coupled to the first power supply voltage, a second terminal coupled to the second power supply voltage, and a gate receiving the reverse mode selection signal.

12. The level shifter of claim 11, wherein the level shift stage includes a first P-type MOS transistor having a first terminal coupled to the first power supply voltage;
a second P-type MOS transistor having a first terminal coupled to a second terminal of the first P-type MOS transistor, a second terminal coupled to the second internal voltage terminal, and a gate receiving the second input signal;
a third P-type MOS transistor having a first terminal coupled to the first power supply voltage, a second terminal coupled to the gate of the first P-type MOS transistor, and a gate coupled to the second internal voltage terminal;
a first N-type MOS transistor having a first terminal coupled to the second internal voltage terminal, a second terminal coupled to the second power supply voltage, and a gate receiving the second input signal; and
a second N-type MOS transistor having a first terminal coupled to the second terminal of the third P-type MOS transistor, a second terminal coupled to the first internal voltage terminal, and a gate receiving the first input signal, and
wherein the mode control unit includes:
a fourth N-type MOS transistor having a first terminal coupled to the first internal voltage terminal, a second terminal coupled to the second power supply voltage, and a gate receiving the reverse mode selection signal; and
a fifth N-type MOS transistor having a first terminal coupled to the second internal voltage terminal, a second terminal coupled to the second power supply voltage, and a gate receiving the mode selection signal.

13. The level shifter of claim 6, wherein the level shift stage includes:
a first P-type MOS transistor having a first terminal coupled to the first power supply voltage and a second terminal coupled to the second internal voltage terminal;
a second P-type MOS transistor having a first terminal coupled to the first power supply voltage, a second terminal coupled to the gate of the first P-type MOS transistor, and a gate coupled to the second internal voltage terminal;
a first N-type MOS transistor having a first terminal coupled to the second internal voltage terminal, a second terminal coupled to the first internal voltage terminal, and a gate receiving the second input signal; and
a second N-type MOS transistor having a first terminal coupled to the second terminal of the second P-type MOS transistor, a second terminal coupled to the first internal voltage terminal, and a gate receiving the first input signal,
wherein the output buffer stage includes:
a third P-type MOS transistor having a first terminal coupled to the first power supply voltage and a gate coupled to the second internal voltage terminal;
a fourth P-type MOS transistor having a first terminal coupled to a second terminal of the third P-type MOS transistor, a second terminal coupled to the output terminal, and a gate receiving the first input signal; and
a third N-type MOS transistor having a first terminal coupled to the output terminal, a second terminal coupled to the second power supply voltage, and a gate receiving the first input signal, and
wherein the mode control unit includes:
a fourth N-type MOS transistor having a first terminal coupled to the first internal voltage terminal, a second other terminal coupled to the second power supply voltage, and a gate receiving the reverse mode selection signal;
a fifth N-type MOS transistor having a first terminal coupled to the output terminal, a second terminal coupled to the second power supply voltage, and a gate receiving the mode selection signal; and
a fifth P-type MOS transistor having a first terminal coupled to the first power supply voltage, a second terminal coupled to the second internal voltage terminal, and a gate receiving the reverse mode selection signal.

14. The level shifter of claim 6, wherein the level shift stage includes:
a first P-type MOS transistor having a first terminal coupled to the first power supply voltage and a second terminal coupled to the second internal voltage terminal;
a second P-type MOS transistor having a first terminal coupled to the first power supply voltage, a second terminal coupled to the gate of the first P-type MOS transistor, and a gate coupled to the second internal voltage terminal;
a first N-type MOS transistor having a first terminal coupled to the second internal voltage terminal, a second terminal coupled to the first internal voltage terminal, and a gate receiving the second input signal; and
a second N-type MOS transistor having a first terminal coupled to the second terminal of the second P-type MOS transistor, a second terminal coupled to the first internal voltage terminal, and a gate receiving the first input signal,
wherein the output buffer stage includes:
a third P-type MOS transistor having a first terminal coupled to the first power supply voltage and a gate coupled to the second internal voltage terminal;
a fourth P-type MOS transistor having a first terminal coupled to a second terminal of the third P-type MOS transistor, a second terminal coupled to the output terminal, and a gate receiving the first input signal; and
a third N-type MOS transistor having a first terminal coupled to the output terminal, a second terminal coupled to the third power supply voltage, and a gate receiving the first input signal, and
wherein the mode control unit includes:
a fourth N-type MOS transistor having a first terminal coupled to the first internal voltage terminal, a second terminal coupled to the second power supply voltage, and a gate receiving the reverse mode selection signal;
a fifth N-type MOS transistor having a first terminal coupled to the third internal voltage terminal, a second terminal coupled to the second power supply voltage, and a gate receiving the reverse mode selection signal; and
a fifth P-type MOS transistor having a first terminal coupled to the first power supply voltage, a second terminal coupled to the output terminal, and a gate receiving the reverse mode selection signal.

15. The level shifter of claim 6, wherein the plurality of input signals includes a first signal with a first phase and a second signal with a second phase, the first and second phases not being the same.

16. The level shifter of claim 6, wherein the mode selection signal indicates either that a given function block outputting the plurality of input signals is operating in a normal mode or that the given function block is operating in a power down mode.

17. The level shifter of claim 16, wherein the output signal of the level shifting unit is based on the plurality of input signals if the mode selection signal indicates the normal mode and is set to a given voltage level if the mode selection signal indicates the power down mode.

18. A method of level shifting, comprising:
generating a plurality of internal voltages based on a plurality of input signals;
controlling the voltage levels of the plurality of internal voltages based on a mode selection signal; and
outputting an output signal based at least in part on the plurality of internal voltages.

19. The method of claim 18, further comprising:
buffering at least a portion of the plurality of internal voltages and outputting the buffered internal voltage as the output signal.

20. The level shifting method of claim 18, wherein the plurality of input signals includes a first signal with a first phase and a second signal with a second phase, the first and second phases not being the same.

21. The level shifting method of claim 18, wherein the plurality of input signals includes a first signal with a first phase and a second signal with a second phase, the first and second phases opposite each other.

22. The level shifting method of claim 18, wherein the mode selection signal indicates either that a given function block outputting the plurality of input signals is operating in a normal mode or that the given function block is operating in a power down mode.

23. The level shifter of claim 22, wherein the output signal of the level shifting unit is based on the plurality of input signals if the mode selection signal indicates the normal mode and is set to a given voltage level if the mode selection signal indicates the power down mode.

24. A level shifter performing the level shifting method of claim 18.

25. A method of level shifting, comprising:
receiving a mode selection signal and a plurality of input signals, the mode selection signal indicating one of a first mode and second mode of operation;
selectively shifting the plurality of input signals if the mode selection signal indicates the first mode of operation;
selectively shifting a plurality of internally generated signals if the mode selection signal indicates the second mode of operation; and
outputting an output signal based at least in part on the selectively shifted signals.

26. The method of claim 25, wherein the output signal is the shifted input signals if the mode selection signal indicates the first mode of operation.

27. The method of claim 25, wherein the output signal is a default voltage level if the mode selection signal indicates the second mode of operation.

28. The method of claim 25, wherein selectively shifting the plurality of internally generated signals is not based on the plurality of input signals.

29. The method of claim 25, wherein the first mode of operation is a normal mode and the second mode of operation is a power down mode.
